(19) United States
(12) Patent Application Publication
(10) Pub. No.: US 2006/0125077 A1
(43) Pub. Date: Jun. 15, 2006

(54) Semiconductor device

(76) Inventors: Sadakazu Akaike, Nagano-shi (JP); Akinobu Inoue, Nagano-shi (JP); Atsunori Kajiki, Nagano-shi (JP); Hiroyuki Takatsu, Nagano-shi (JP); Takashi Tsubota, Nagano-shi (JP); Norio Yamanishi, Nagano-shi (JP)

Correspondence Address: LADAS & PARRY LLP, 224 SOUTH MICHIGAN AVENUE, SUITE 1600, CHICAGO, IL, 60604, US

(21) Appl. No.: 11/291,599

(22) Filed: Dec. 1, 2005

(30) Foreign Application Priority Data
Dec. 10, 2004 (JP) 2004-358543

(51) Int. Cl. H01L 23/48

(52) U.S. Cl. 257/690

(57) ABSTRACT

A semiconductor device is provided that includes a semiconductor chip, a substrate on which the semiconductor chip is mounted, a mounting terminal that is arranged on a first side of the substrate, and a testing terminal that is arranged on a second side of the substrate which second side is opposite the first side of the substrate.

### BACKGROUND OF THE INVENTION

1. Field of the Invention

The present invention relates to a semiconductor device that includes a testing terminal arranged on a semiconductor chip mounting substrate.

2. Description of the Related Art

A semiconductor device that is referred to as a single chip package may include testing terminals for testing an electrical signal of the semiconductor device in addition to mounting terminals for connecting the semiconductor device to another substrate such as a motherboard. FIG.1 is a cross-sectional view of a semiconductor device that includes such testing terminals.

The semiconductor device 10 shown in FIG.1 includes a substrate 11, a semiconductor chip 25, mounting terminals 41, and testing terminals 42. The semiconductor chip 25 and wires 28 are sealed by molded resin 29.

The substrate 11 includes a base material 12, vias 13 that penetrate through the base material 12, upper wiring 14, an upper resin layer 15, vias 16 and 33, wiring 17, solder resists 21 and 38, lower wiring 31, a lower resin layer 32, and connection pads 35 and 37. It is noted that in FIG. 1, a region on the upper resin layer 15 on which the semiconductor chip 25 is mounted is referred to as a chip mounting region A.

The upper wiring 14 is arranged on an upper surface 12A of the base material 12 and is electrically connected to the vias 13. The upper resin layer 15 is arranged to cover the upper wiring 14 and the upper surface 12A of the base material 12. The vias 16 are arranged penetrating through the upper resin layer 15, the end portions of the vias 16 on one side being connected to the upper wiring 14, and the end portions of the vias 16 on the other side being connected to the wiring 17. The wiring 17 is arranged on the upper resin layer 15 and includes connecting portions 19 to which the wires 28 are connected. The solder resist 21 is arranged on the upper resin layer 15, and exposes the chip mounting region A and the connecting portions 19 while covering portions of the wiring 17 other than the connections portions 19.

The lower wiring 31 is arranged on a lower surface 12B of the base material 12, and is electrically connected to the vias 13. The lower resin layer 32 is arranged to cover the lower wiring 31 and the lower surface 12B of the base material 12. The vias 33 are arranged penetrating through the lower resin layer 32, the end portions of the vias 33 on one side being connected to the connection pads 35 or the connection pads 37, and the end portions of the vias 33 on the other side being connected to the lower wiring 31. The connection pads 35 and 37 are arranged on a surface 32A of the lower resin layer 32 and are connected to the vias 33. The connection pads 37 are used for mounting the mounting terminals 41, and the connection pads 35 are used for mounting the testing terminals 42.

The semiconductor chip 25 includes electrode pads 26 that are electrically connected to the connecting portions 19 via the wires 28. The semiconductor chip 25 is mounted on the chip mounting region A on the upper resin layer 15.

The testing terminals 42 correspond to external terminals for testing an electrical signal of the semiconductor device 10. The testing terminals 42 are mounted on the connection pads 35 that are arranged on the lower surface 12B side of the base material 12 (i.e., lower surface 32A of the lower resin layer 32).

In recent years and continuing, there is an increasing demand for miniaturization and densification of the semiconductor device, for example, and in turn, a technique has been developed for stacking plural semiconductor devices and mounting the stacked semiconductor devices on another substrate such as a motherboard. It is noted that such a technique is disclosed in Japanese Laid-Open Patent No. 2001-339011, for example. FIG. 2 is a cross-sectional view of two semiconductor devices that are stacked one on top of the other. It is noted that components of the stacked semiconductor devices 50 and 70 shown in FIG. 2 that are identical to the components of the semiconductor device 10 shown in FIG. 1 are assigned the same numerical references.

In FIG. 2, the semiconductor device 50 has the semiconductor device 70 stacked thereon and is configured to be connected to another substrate such as a motherboard (not shown). The semiconductor device 50 includes a substrate 51, a semiconductor chip 55, and mounting terminals 62.

The substrate 51 includes a base material 12, vias 13, upper wiring 14, an upper resin layer 15, vias 16 and 33, solder resists 21 and 38, lower wiring 31, a lower resin layer 32, connecting portions 53, and connection pads 54 and 61. The connecting portions 53 and the connection pads 54 are arranged on the upper resin layer 15 and are electrically connected to the vias 16. The connecting portions 53 are electrically connected to electrode pads 56 of the semiconductor chip 55. The connection pads 54 are connected to mounting terminals 72 that are arranged on the semiconductor device 70. The connection pads 61 are arranged on a lower surface 32A of the lower resin layer 32, and are electrically connected to the vias 33.

The semiconductor chip 55 includes the electrode pads 56 that are electrically connected to stud bumps 57. The stud bumps 57 are electrically connected to the connecting portions 53 by solder 58. Also, underfill resin 59 is arranged between the semiconductor chip 55 and the substrate 51. The mounting terminals 62 are arranged on the connection pads 61 and are configured to be connected to another substrate such as a motherboard (not shown).

The semiconductor device 70 is mounted on the connection pads 54 of the semiconductor device 50, and includes a substrate 71, a semiconductor chip 25, and mounting terminals 72. The semiconductor chip 25 and wires 28 are sealed by molded resin 29.

The substrate 71 includes a base material 12, vias 13, upper wiring 14, an upper resin layer 15, vias 16 and 33, wiring 17, solder resists 21 and 38, lower wiring 31, a lower resin layer 32, and connection pads 37. The mounting terminals 72 are electrically connected to the connection pads 54 of the semiconductor device 50. By connecting the mounting terminals 72 to the connection pads 54, electrical connection may be realized between the semiconductor device 50 and the semiconductor device 70.

By stacking the two semiconductors 50 and 70, and mounting the stacked semiconductor device structure on another substrate such as a motherboard as is described above, the outer size of a region on the other substrate that is required for mounting the semiconductors 50 and 70 may be reduced, and the semiconductors 50 and 70 may be mounted at a higher density.

In the illustrated example of FIG. 1, since the semiconductor device 10 has two types of terminals (i.e., mounting terminals 41 and testing terminals 42) arranged on one side (i.e., the lower surface 32A side of the lower resin layer 32) of the substrate 11, the outer size of the substrate 11 may be relatively large, and the semiconductor device 10 cannot be adequately miniaturized.

In the illustrated example of FIG. 2 in which the two semiconductors 50 and 70 realize a stacked semiconductor device structure, densification of the semiconductor devices 50 and 70 may be realized. However, in this example, even if testing terminals similar to those of the semiconductor device 10 are provided, the testing terminals end up facing the semiconductor device 50 so that testing of an electrical signal between the semiconductor device 50 and the semiconductor device 70 may not be performed.

### SUMMARY OF THE INVENTION

The present invention has been conceived in response to one or more of the problems described above, and it provides a semiconductor device that may be miniaturized and is adapted to enable testing of an electrical signal of the present semiconductor device and another semiconductor device that are arranged into a stacked semiconductor device structure.

According to an embodiment of the present invention, a semiconductor device is provided that includes:

a semiconductor chip;

a substrate on which the semiconductor chip is mounted;

a mounting terminal that is arranged on a first side of the substrate; and

a testing terminal that is arranged on a second side of the substrate which second side is opposite the first side of the substrate.

In one aspect of the present embodiment, by arranging the testing terminal on the second side of the substrate opposite the first side of the substrate on which the mounting terminal is arranged, the outer size of the substrate may be reduced and miniaturization of the semiconductor device may be realized, for example. In another aspect of the present embodiment, even when another semiconductor device is mounted on the semiconductor device of the present embodiment, testing of an electric signal of the semiconductor devices may be performed, for example.

According to a preferred embodiment of the present invention, the semiconductor chip is mounted on the second side of the substrate, and the testing terminal protrudes from the second side of the substrate further than the semiconductor chip.

In one aspect of the present embodiment, by arranging the testing terminal to protrude further than the semiconductor chip, the semiconductor chip may be prevented from interfering with a process of connecting a probe of a testing device to the testing terminal so that the probe and the testing terminal may be easily connected, for example.

According to another preferred embodiment of the present invention, the semiconductor chip is connected to the substrate by a wire, and the testing terminal protrudes from the second side of the substrate further than the wire.

In one aspect of the present embodiment, by arranging the testing terminal to protrude further than the wire, the wire may be prevented from interfering with a process of connecting a probe of a testing apparatus to the testing terminal so that the probe and the testing terminal may be easily connected, for example.

According to another preferred embodiment of the present invention, the semiconductor chip is covered by resin, and a portion of the testing terminal is exposed through the resin.

In one aspect of the present embodiment, the resin may control the positioning of the testing terminal with respect to the substrate, for example.

### BRIEF DESCRIPTION OF THE DRAWINGS

FIG. 1 is a cross-sectional view of a semiconductor device including testing terminals;

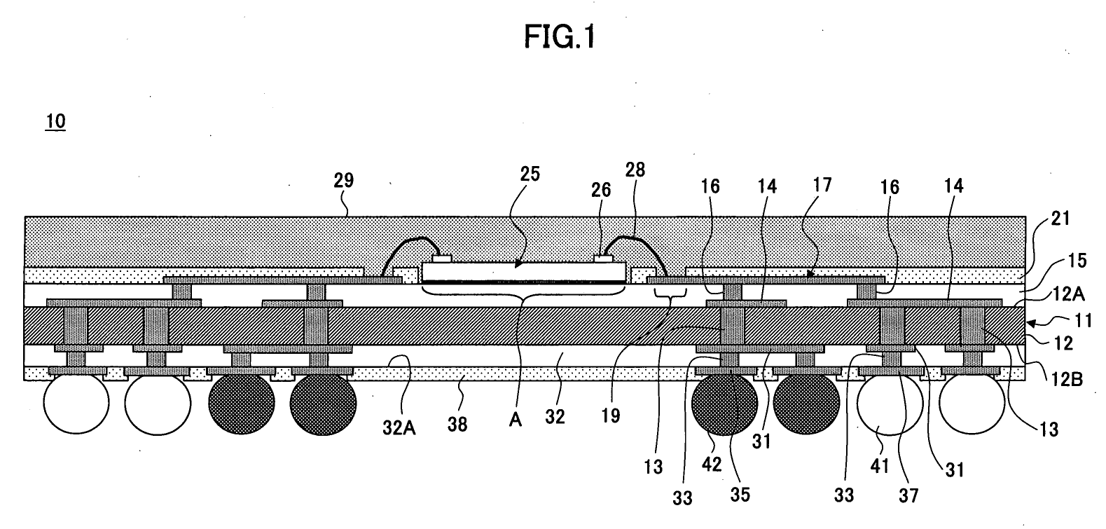

FIG. 2 is a cross-sectional view of two semiconductor devices that are stacked one on top of the other;

FIG. 3 is a plan view of a semiconductor device according to an embodiment of the present invention;

FIG. 4 is a cross-sectional view of the semiconductor device shown in FIG. 3 cut across line B-B;

FIG. 5 is a cross-sectional view of a structure realized by mounting the semiconductor device according to the present embodiment on another semiconductor device;

FIG. 6 is a diagram illustrating a first process step for manufacturing the semiconductor device according to the present embodiment;

FIG. 7 is a diagram illustrating a second process step for manufacturing the semiconductor device according to the present embodiment;

FIG. 8 is a diagram illustrating a third process step for manufacturing the semiconductor device according to the present embodiment;

FIG. 9 is a diagram illustrating a fourth process step for manufacturing the semiconductor device according to the present embodiment;

FIG. 10 is a diagram illustrating a fifth process step for manufacturing the semiconductor device according to the present embodiment;

FIG. 11 is a cross-sectional view of a semiconductor device including testing terminals on both sides of its substrate according to another embodiment of the present invention;

FIG. 12 is a cross-sectional view of a structure realized by mounting another semiconductor device on the semiconductor device shown in FIG. 11;

FIG. 13 is a cross-sectional view of a structure realized by mounting the semiconductor device shown in FIG. 4 on the semiconductor device shown in FIG. 11;

FIG. 14 is a cross-sectional view of a semiconductor device including electronic components and testing terminals according to another embodiment of the present invention; and

FIG. 15 is a cross-sectional view of a structure realized by connecting the semiconductor device shown in FIG. 14 to a motherboard.

### DETAILED DESCRIPTION OF THE PREFERRED EMBODIMENTS

In the following, preferred embodiments of the present invention are described with reference to the accompanying drawings.

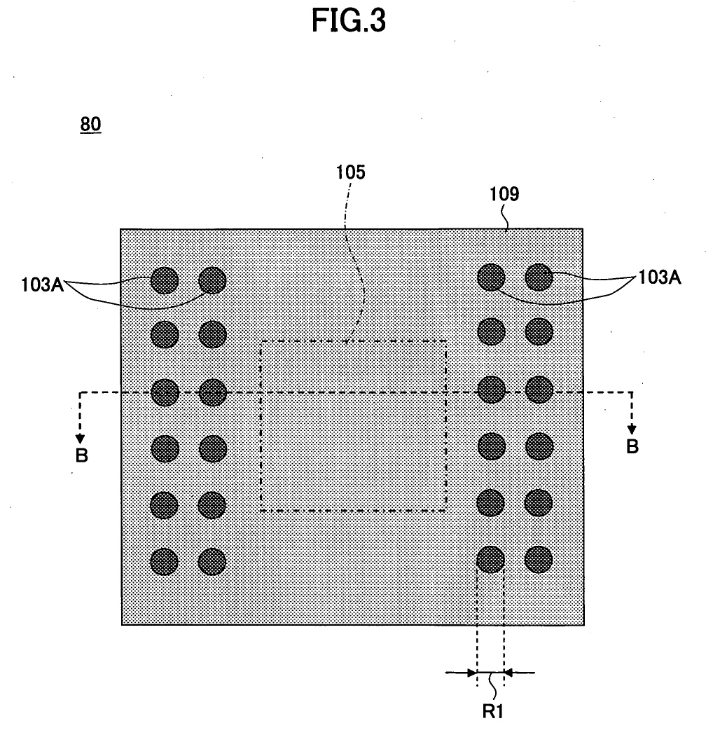

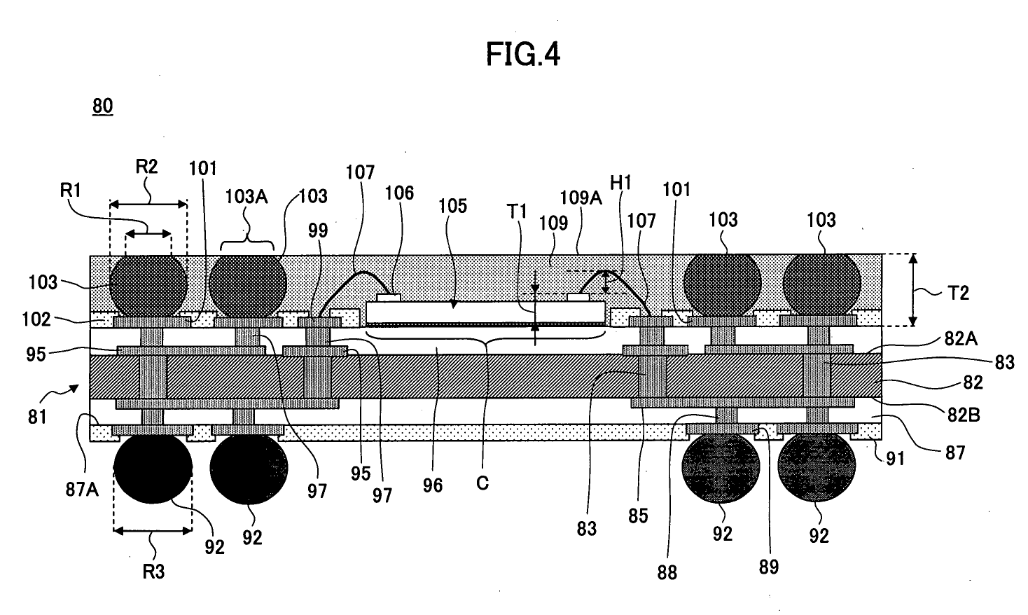

First, a semiconductor device 80 according to an embodiment of the present invention is described with reference to FIGS. 3 and 4. FIG. 3 is a plan view of the semiconductor device 80 according to the present embodiment, and FIG. 4 is a cross-sectional view of the semiconductor device 80 cut across line B-B shown in FIG. 3. It is noted that in FIG. 3, R1 represents the diameter of flat surfaces 103A of testing terminals 103 that are exposed through molded resin 109 (referred to as ‘diameter R1’ hereinafter). It is also noted that in FIG. 4, C represents a region on an upper resin layer 96 on which a semiconductor chip 105 is mounted (referred to as ‘chip mounting region C’ hereinafter), H1 represents the height of wires 107 with respect to an electrode pad 106 (referred to as ‘height H1’ hereinafter), T1 represents the thickness of the semiconductor chip 105 including the electrode pad 106 (referred to as ‘thickness T1’ hereinafter), T2 represents the thickness of the molded resin 109 with respect to the upper surface of the upper resin layer 96 (referred to as ‘thickness T2’ hereinafter), R2 represents the diameter of the substantially spherical configuration of the testing terminals 103 (referred to as ‘diameter R2’), and R3 represents the diameter of the substantially spherical configuration of mounting terminals 92 (referred to as ‘diameter R3’ hereinafter).

According to the present embodiment, the semiconductor device 80 includes a substrate 81, the semiconductor chip 105, mounting terminals 92, and testing terminals 103. The substrate 81 includes a base material 82, vias 83, lower wiring 85, a lower resin layer 87, vias 88 and 97, connection pads 89 and 101, solder resists 91 and 102, upper wiring 95, the upper resin layer 96, and wire connecting portions 99.

The base material 82 is a plate member that may be made of a resin base material or a ceramic base material, for example. The vias 83 are arranged to penetrate through the base material 82. The vias 83 are provided for realizing electrical connection between the upper wiring 95 and the lower wiring 85. The lower wiring 85 is arranged on a lower surface 82B of the base material 82 and is electrically connected to the vias 83. The lower resin layer 87 is arranged to cover the lower wiring 85 and the lower surface 82B of the base material 82. The vias 88 are arranged penetrating through the lower resin layer 87, the end portions of the vias 88 at one side being connected to the lower wiring 85, and the end portions of the vias 88 on the other side being connected to the connection pads 89.

The connection pads 89 are arranged on a surface 87A of the lower resin layer 87, and are electrically connected to the vias 88. The connection pads 89 are used for mounting the mounting terminals 92. The solder resist 91 is arranged to cover the surface 87A of the lower resin layer 87 while exposing the connection pads 89.

The upper wiring 95 is arranged on an upper surface 82A of the base material 82, and is electrically connected to the vias 83. The upper resin layer 96 is arranged to cover the upper wiring 95 and the upper surface 82A of the base material 82. It is noted that the chip mounting region C on which the semiconductor chip 105 is mounted is created on the upper resin layer 96. The vias 97 are arranged penetrating through the upper resin layer 96, the end portions of the vias 97 on one side being connected to the upper wiring 95, and the end portions of the vias 97 on the other side being connected to the wire connecting portions 99 or the connection pads 101.

The wire connecting portions 99 are arranged on the upper resin layer 96, and are electrically connected to the vias 97. The wire connecting portions 99 are used for mounting the wires 107 that are connected to the semiconductor chip 105. The connection pads 101 are arranged on the upper resin layer 96, and are electrically connected to the vias 97. The testing terminals 103 are arranged on the connection pads 101. The solder resist 102 is arranged to cover the upper surface of the upper resin layer 96 while exposing the connection pads 101 and the chip mounting region C.

The semiconductor chip 105 is mounted on the chip mounting region C on the upper resin layer 96 by adhesive. The semiconductor chip 105 includes the electrode pads 106 that are electrically connected to the wire connecting portions 99 via the wires 107. The thickness T1 of the semiconductor chip 105 may be 0.15 mm, for example. Also, the height H1 of the wires 107 may be 0.1 mm, for example.

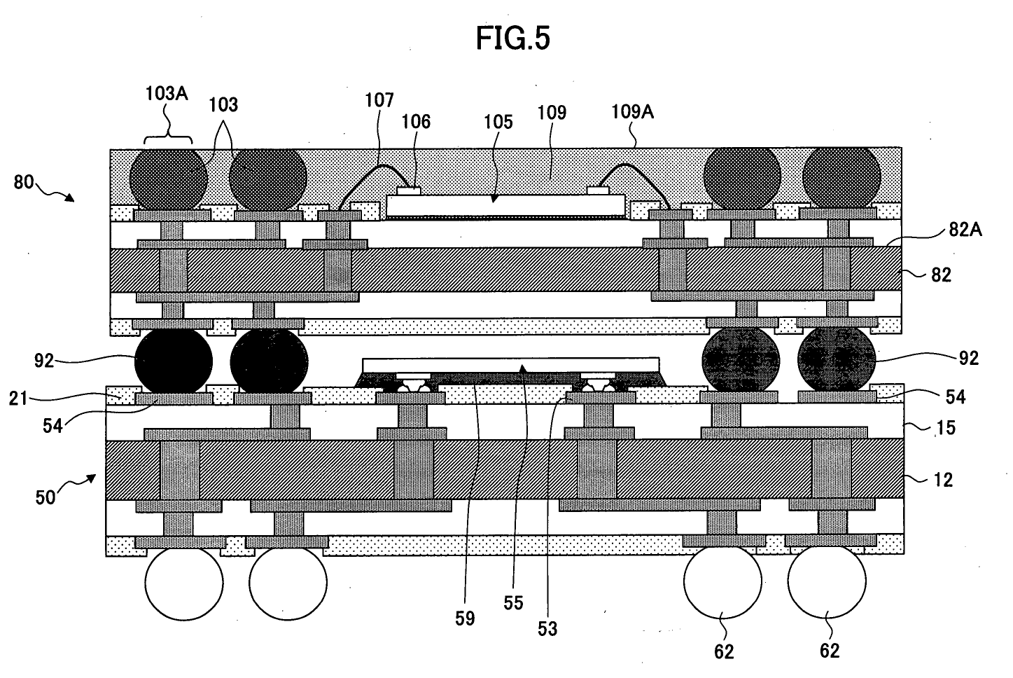

According to one embodiment, the mounting terminals 92 may correspond to external terminals that are electrically connected to another semiconductor device such as the semiconductor device 50 (see FIG. 5). The mounting terminals 92 are arranged on the lower surface 87A of the lower resin layer 87, and are electrically connected to the connection pads 89. It is noted that solder balls or metal posts may be used as the mounting terminals 92, for example. In a case where solder balls are used as the mounting terminals 92, the diameter R3 of the mounting terminals 92 may be 0.4 mm, for example.

The testing terminals 103 are used for testing an electrical signal. In one embodiment, electrical signal testing may be performed by connecting probes of a testing device (not shown) to the testing terminals 103. The testing terminals 103 are arranged on the upper surface of the upper resin layer 96, namely, on the opposite side of the substrate 81 with respect to the side on which the mounting terminals 92 are arranged (i.e., surface 87A of the lower resin layer 87), and the testing terminals 103 are electrically connected to the connection pads 101.

By arranging the testing terminals 103 on the opposite side of the substrate 81 (e.g., upper surface of the upper resin layer 96) with respect to the side of the substrate 81 on which the mounting terminals 92 are arranged (e.g., lower surface 87A of the lower resin layer 87), connection pads for mounting the testing terminals 103 do not have to be arranged on the side of the substrate 81 one which the mounting terminals 92 are arranged so that the outer size of the substrate 81 may be reduced and the semiconductor device 80 may be miniaturized.

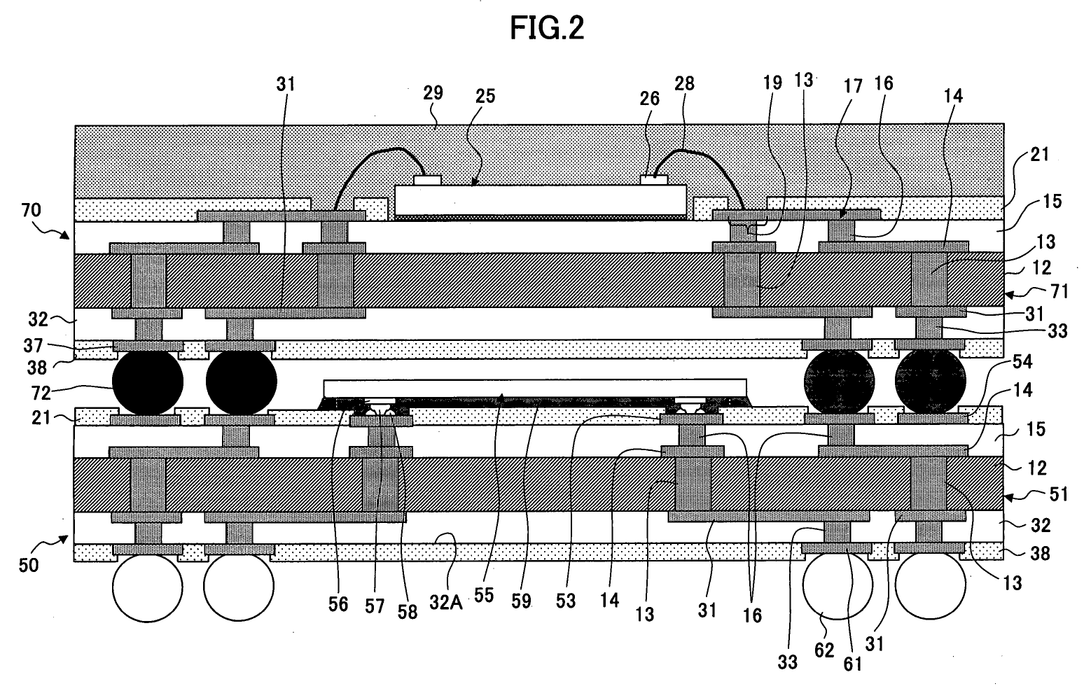

FIG. 5 is a cross-sectional view of a structure realized by mounting the semiconductor device 80 of the present embodiment on the semiconductor device 50 shown in FIG. 2. When the semiconductor device 80 of the present embodiment is mounted on the semiconductor device 50 as is shown in FIG. 5, for example, probes of a testing device (not shown) may be connected to the testing terminals 103 that are arranged on the upper surface side of the upper resin layer 96, namely, the side that is not facing the semiconductor device 50, so that testing of an electrical signal of the semiconductor device 50 and the semiconductor device 80 may be performed.

In the illustrated embodiment, the testing terminals 103 have substantially spherical configurations with flat surfaces 103A arranged at the upper portions of the spherical configurations. It is noted that the testing terminals 103 are preferably arranged to protrude further than the wires 107.

By arranging the testing terminals 103 to protrude further than the wires 107, the wires 107 may be prevented from interfering with a process of connecting the probes of the testing device to the flat surfaces 103A of the testing terminals 103. In turn, connection of the probes of the testing device to the testing terminals 103 may be facilitated. Also, in a case where the semiconductor chip 105 is flip chip connected to the substrate 81, the testing terminals 103 are preferably arranged to protrude further than the semiconductor chip 105.

In the illustrated embodiment, the molded resin 109 for protecting the wires 107 is arranged to expose the flat surfaces 103A of the testing terminals 103 while covering the other portions of the testing terminals 103. The flat surfaces 103A of the testing terminals 103 and the surface 109A of the molded resin 109 are arranged to be substantially coplanar. By arranging the molded resin 109 to expose the flat surfaces 103A of the testing terminals while covering the other portions of the testing terminals 103, the peripheries of the testing terminals 103 may be supported by the molded resin 109, and the positioning of the testing terminals 103 with respect to the substrate 81 may be controlled.

It is noted that solder balls or cylindrical/prismatic metal posts may be used as the testing terminals 103, for example. In a case where metal posts are used as the testing terminals 103, metal posts made of copper may be connected to the connection pads 101 by solder, or the metal posts may be created by inducing precipitation growth of plating on the connection pads 101, for example. In a case where solder balls are used as the testing terminals 103, the diameter R2 of the testing terminals 103 may be 0.4 mm, for example, and in such a case, the diameter R1 of the flat surfaces 103A exposed through the molded resin 109 may be 0.25 mm, for example. Also, the thickness T2 of the molded resin 109 may be 0.3 mm, for example.

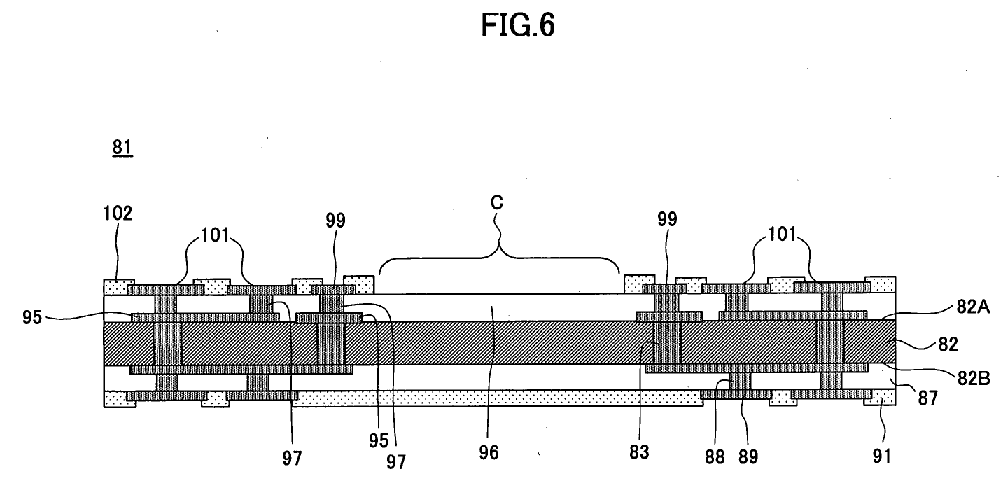

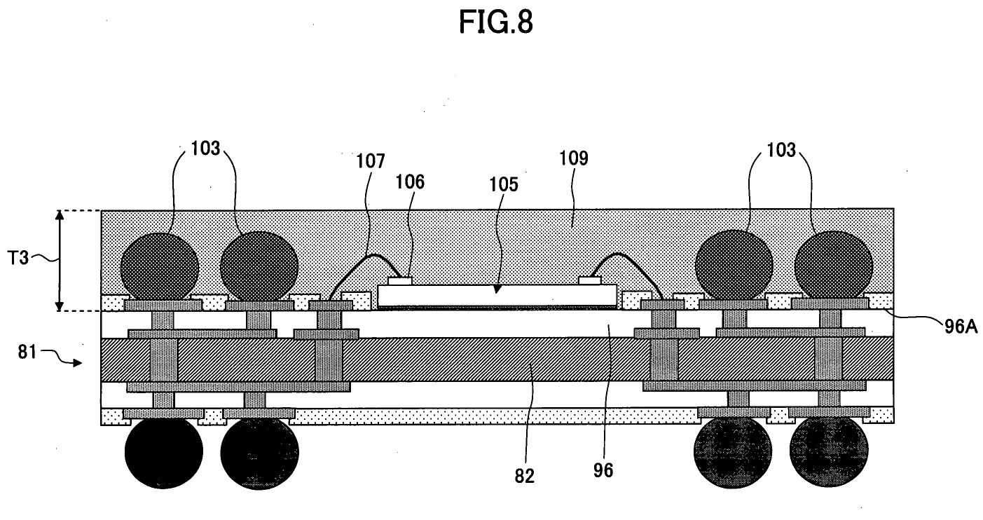

In the following, a method of fabricating the semiconductor device 80 of the present embodiment is described with reference to FIGS. 6 through 10. FIGS. 6 through 10 are diagrams illustrating process steps for fabricating the semiconductor device 80. It is noted that in FIGS. 6 through 10, components that are identical to those shown in FIG. 4 are given the same numerical references. Also, it is noted that in FIG. 8, T3 represents the thickness of the molded resin 109 with respect to the upper surface of the upper resin layer 96 before it is polished (referred to as ‘thickness T3’ hereinafter).

According to the illustrated embodiment, first, as is shown in FIG. 6, the substrate 81 as is described with reference to FIG. 4 is fabricated through a conventional method for fabricating a substrate, for example. In this case, the connection pads 101 are created on the upper surface of the upper resin layer 96 (i.e., opposite side with respect to the side on which the connection pads 89 for mounting the mounting terminals 92 are formed).

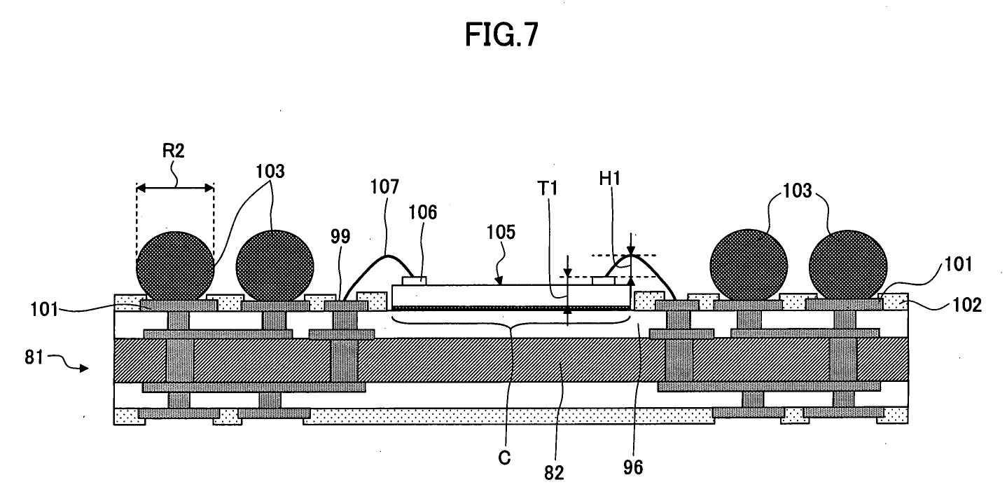

Then, as is shown in FIG. 7, the semiconductor chip 105 is mounted on the chip mounting region C on the upper resin layer 96 via adhesive, and the electrodes 106 and the wire connecting portions 99 are connected via the wires 107. Then, the testing terminals 103 are connected to the connection pads 101. In one example, the thickness T1 of the semiconductor chip 105 may be 0.15 mm, and the height H1 of the wires 107 may be 0.1 mm. Also, in a case where solder balls are used as the testing terminals 103, the diameter R2 of the testing terminals 103 may be 0.4 mm, for example.

Then, as is shown in FIG. 8, the molded resin 109 is arranged to cover the wires 107, the semiconductor chip 105, and the testing terminals 103. It is noted that the thickness T3 of the molded resin 109 is preferably arranged to be an adequate thickness for covering the wires 107.

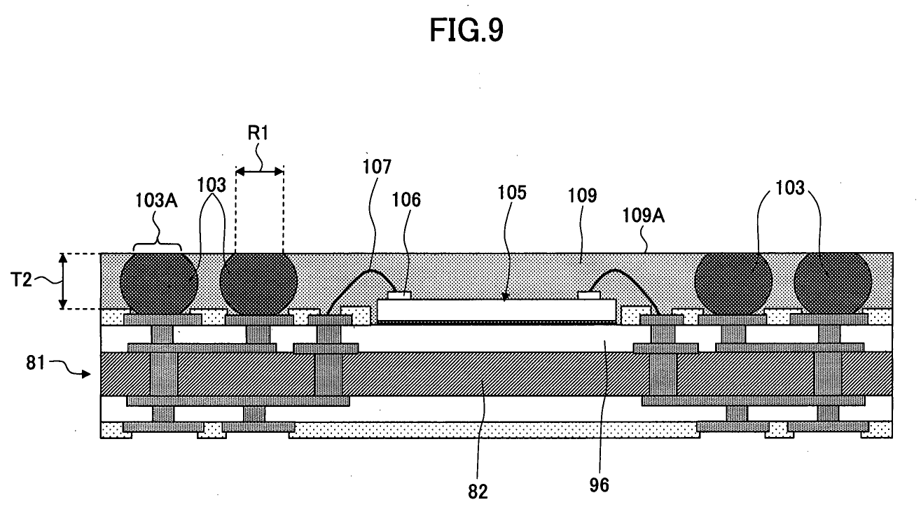

Then, as is shown in FIG. 9, a polishing surface of the molded resin 109 is polished so that the polishing surface may be arranged to be parallel with the planar direction of the base material 82, and as a result, the upper portions of the testing terminals 103 are exposed through the molded resin 109. In this case, the testing terminals 103 are polished along with the molded resin 109 so that the upper portions of the testing terminals 103 are arranged into the flat surfaces 103A exposed through the molded resin 109. It is noted that the thickness T2 of the molded resin 109 after being polished may be 0.3 mm, for example. The diameter R1 of the flat surfaces 103A of the testing terminals 103 may be 0.25 mm, for example.

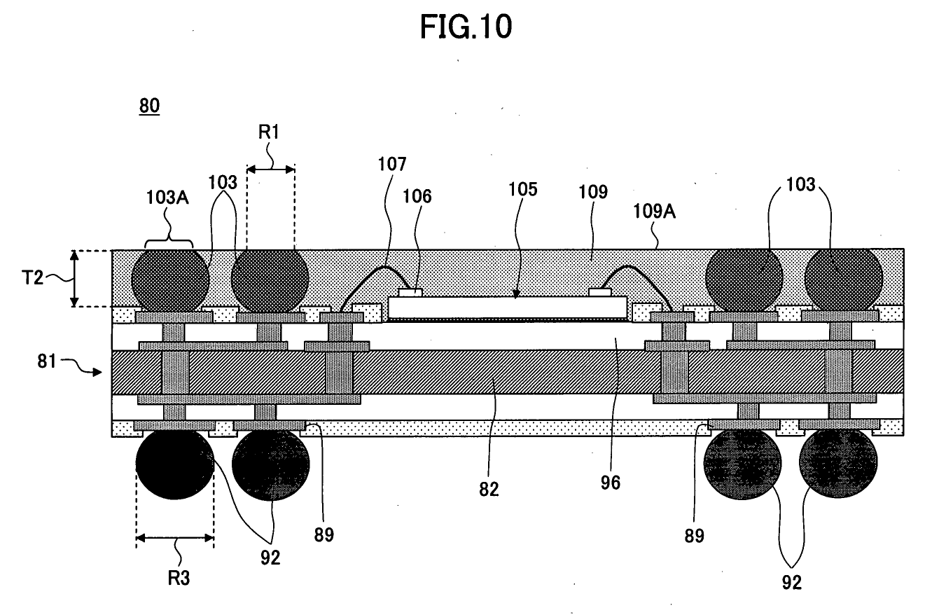

Then, as is shown in FIG. 10, the mounting terminals 92 are connected to the connection pads 89, and the semiconductor device 80 is thus fabricated. It is noted that in a case where solder balls are used as the mounting terminals 92, the diameter R3 of the mounting terminals 92 may be 0.4 mm, for example.

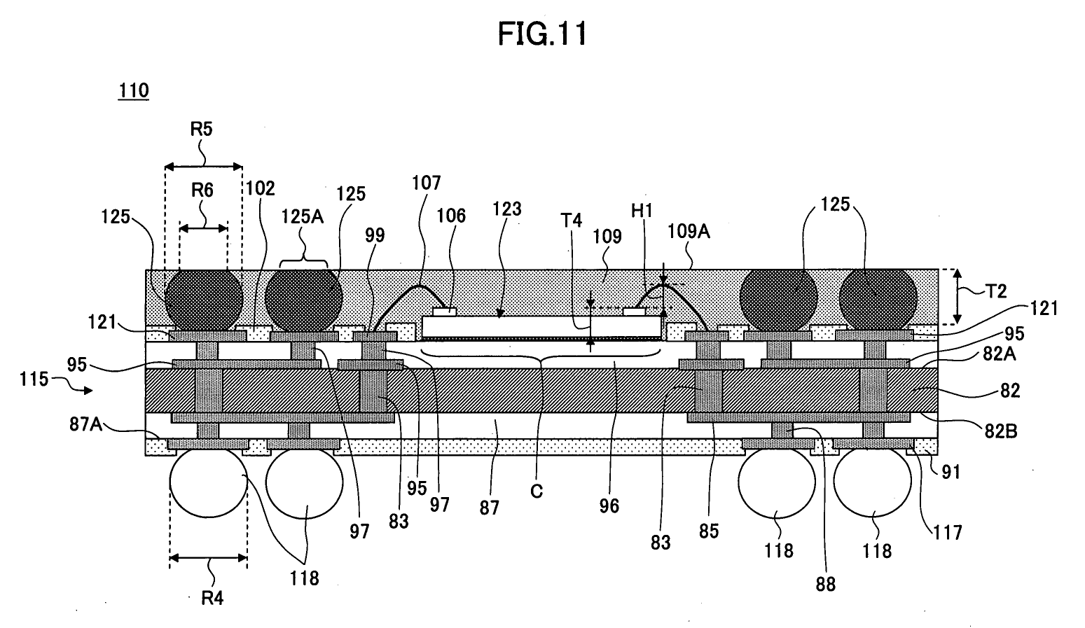

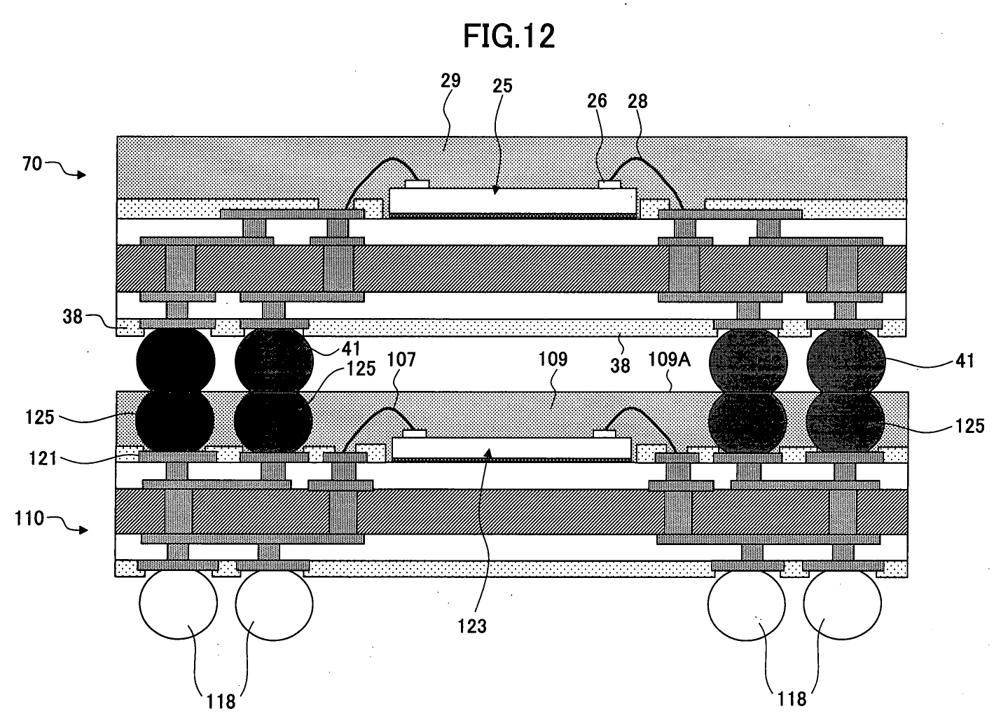

In the following, a modified example of the semiconductor device 80 is described with reference to FIGS. 11 and 12. In the semiconductor device 110 according to this modified example, mounting terminals for realizing connection with another semiconductor device are arranged on the upper surface of the upper resin layer 96 instead of the testing-terminals 103. In other words, the semiconductor device 110 has mounting terminals arranged on both sides of its substrate.

FIG. 11 is a cross-sectional view of the semiconductor device 110, and FIG. 12 is a cross-sectional view of a structure realized by mounting the semiconductor device 70 shown in FIG. 2 on the semiconductor device 110. It is noted that in FIG. 11, T4 represents the thickness of a semiconductor chip 123 including electrode pads 106 (referred to as ‘thickness T4’ hereinafter) Also, it is noted that in FIGS. 11 and 12, components that are identical to those of the semiconductor device 80 shown in FIG. 4 are given the same numerical references.

According to the illustrted embodiment, the semiconductor device 110 includes a substrate 115, the semiconductor chip 123, and mounting terminals 118 and 125. The semiconductor chip 123 is adhered to a chip mounting region C on an upper resin layer 96 by adhesive.

The substrate includes a base material 82, vias 83, lower wiring 85, a lower resin layer 87, vias 88 and 97, solder resists 91 and 102, upper wiring 95, an upper resin layer 96, wire connecting portions 99, and connection pads 117 and 121. The connection pads 117 are for mounting the mounting terminals 118, and are arranged on a surface 87A of the lower resin layer 87. The connection pads 121 are for mounting the mounting terminals 125, and are mounted on the upper surface of the upper resin layer 96.

The semiconductor chip 123 includes electrode pads 106 that are electrically connected to the wire connecting portions 99 via the wires 107. In one example, the thickness T4 of the semiconductor device 123 may be 0.15 mm. Also, the height H1 of the wires 107 may be 0.1 mm, for example.

The mounting terminals 118 correspond to external connection terminals for realizing connection with another substrate such as a motherboard. The mounting terminals 118 have substantially spherical configurations and are arranged on the connection pads 117. It is noted that solder balls or metal posts may be used as the mounting terminals 118, for example. In a case where solder balls are used as the mounting terminals 118, the diameter R4 of the mounting terminals 118 may be 0.4 mm, for example.

The mounting terminals 125 have substantially spherical configurations with flat surfaces 125A arranged at the upper portions of the spherical configurations. It is noted that the mounting terminals 125 are preferably arranged to protrude further than the wires 107.

As is shown in FIG. 12, by arranging the mounting terminals 125 protruding further than the wires 107 on the connection pads 121, the mounting terminals 125 and the mounting terminals 41 may be connected at a position that is distanced away from the position of the wires 107 upon mounting the semiconductor device 70 on the semiconductor device 110. In this way, the positional relation between the semiconductor chip 123 and the wires 107 with respect to height directions does not have to be taken into account so that the mounting of the semiconductor device 70 onto the semiconductor device 110 may be facilitated. It is noted that in a case where the semiconductor device 123 is flip chip connected to the substrate 115, the mounting terminals 125 are preferably arranged to protrude further than the semiconductor chip 123.

In the illustrated embodiment, the mounting terminals 125 are arranged on the connection pads 121, and the molded resin 109 is arranged to expose the surfaces 125A of the mounting terminals 125 while covering the other portions of the mounting terminals 125. Also, the surfaces 125A of the mounting terminals 125 are arranged to be substantially coplanar with a surface 109A of the molded resin 109.

By arranging the molded resin 109 to expose the surfaces 125A while covering the other portions of the mounting terminals 125, the positioning of the mounting terminals 125 with respect to the substrate 115 may be controlled. It is noted that solder balls or cylindrical/prismatic metal posts may be used as the mounting terminals 125, for example. In a case where metal posts are used as the mounting terminals 125, metal posts made of copper may be connected to the connection pads 121 by solder, or the metal posts may be created by inducing precipitation growth of plating on the connection pads 121, for example. In one example, the diameter R5 of the mounting terminals 125 may be 0.4 mm, and in this case, the diameter R6 of the surfaces 125A of the mounting terminals 125 that are exposed by the molded resin 109 may be 0.25 mm, for example.

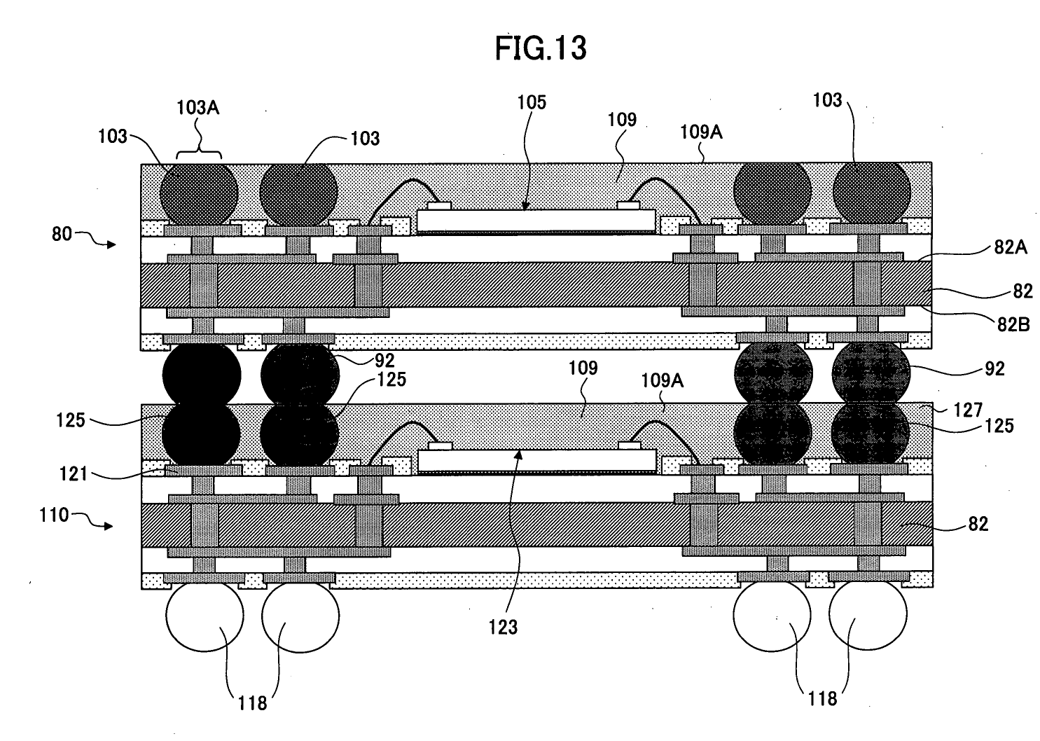

FIG. 13 is a cross-sectional view of a structure realized by mounting the semiconductor device 80 shown in FIG. 4 on the semiconductor device 110. As is shown in FIG. 13, the semiconductor device 80 having the testing terminals 103 arranged on the upper surface 82A side of the base material 82 may be mounted on the semiconductor device 110 so that testing of an electrical signal between the semiconductor device 80 and the semiconductor device 110 may be performed.

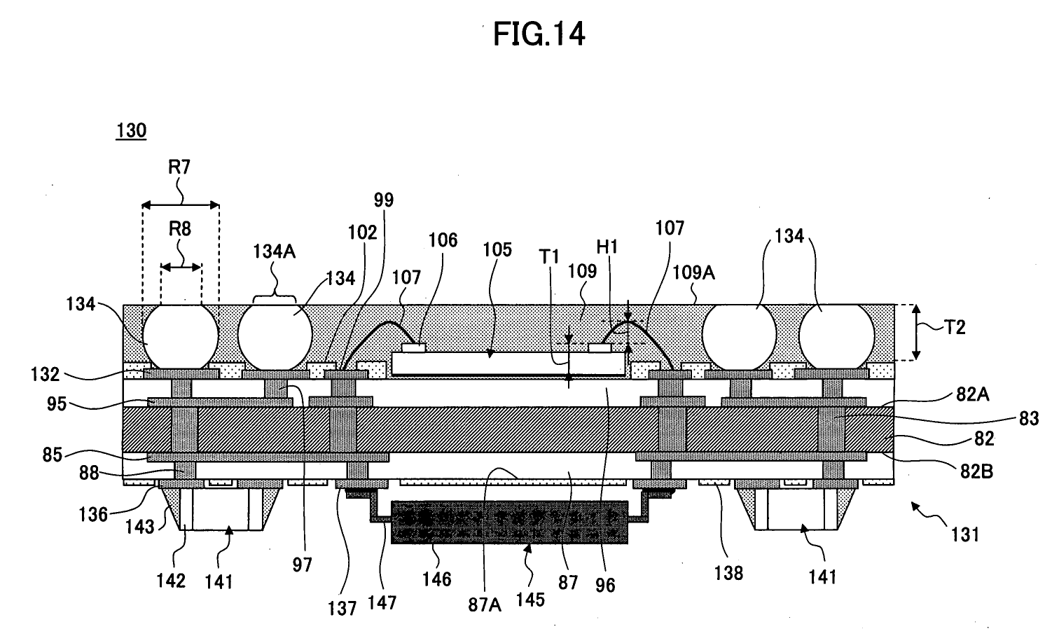

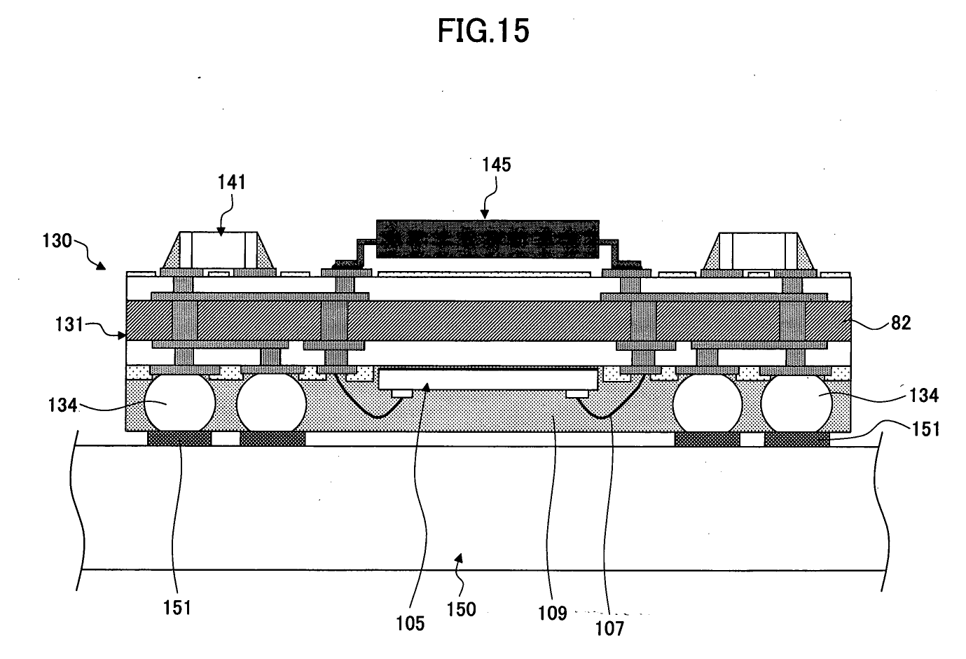

In the following, another modified example of the semiconductor device 80 is described with reference to FIGS. 14 and 15. The semiconductor device 130 according to the present modified example includes mounting terminals 134 for realizing connection with another substrate such as a motherboard arranged on the upper surface 82A side of the base material 82 and electronic components arranged on the lower surface 82B side of the base material 82. FIG. 14 is a cross-sectional view of the semiconductor device 130, and FIG. 15 is a cross-sectional view of a structure realized by connecting the semiconductor device 130 to a motherboard 150. It is noted that in FIGS. 14 and 15, components that are identical to those of the semiconductor device 80 shown in FIG. 4 are given the same numerical references.

In the illustrated embodiment, the semiconductor device 130 includes a substrate 131, a semiconductor chip 105, mounting terminals 134, individual components 141, and a package 145 with a semiconductor chip (not shown) accommodated therein.

The substrate 131 includes a base material 82, vias 83, lower wiring 85, a lower resin layer 87, vias 88 and 97, upper wiring 95, upper resin layer 96, wire connecting portions 99, solder resists 102 and 138, connection pads 132, first connecting portions 136, and second connecting portions 137. The connection pads 132 are arranged on the upper resin layer 96 and are electrically connected to the vias 97. The connection pads are used for mounting the mounting terminals 134.

The first connecting portions 136 are arranged on a surface 87A of the lower resin layer 87, and are electrically connected to the vias 88. The first connecting portions 136 are configured to realize electrical connection with the individual components 141. The second connecting portions 137 are arranged on the surface 87A of the lower resin layer 87, and are electrically connected to the vias 88. The second connecting portions 137 are configured to realize electrical connection with the package 145. The solder resist 138 is arranged on the surface 87A of the lower resin layer 87 at a region between the first connecting portions 136 and the second connecting portions 137.

The mounting terminals 134 have substantially spherical configurations with flat surfaces 134A arranged at the upper portions of the spherical configurations. The mounting terminals 134 are mounted on the connection pads 132, and are arranged to protrude further than the wires 107. It is noted that solder balls or metal posts may be used as the mounting terminals 134, for example.

As is shown in FIG. 15, by arranging the mounting terminals 134 protruding further than the wires 107 on the connection pads 132, the connection pads 151 of the motherboard 150 and the mounting terminals 134 may be electrically connected at a position distanced away from the wires 107 upon mounting the semiconductor device 130 on the motherboard 150. In this way, the semiconductor device 130 may be easily mounted on the motherboard 150 without having to take into account the positions of the semiconductor chip 105 and the wires 107. In a case where the semiconductor chip 105 is flip chip connected to the substrate 131, the mounting terminals are preferably arranged to protrude further than the semiconductor chip 105.

In the illustrated embodiment, the molded resin 109 is arranged to expose the surfaces 134A of the mounting terminals 134 while covering the other portions of the mounting terminals 134. The surfaces 134A of the mounting terminals 134 are arranged to be substantially coplanar with the surface 109A of the molded resin 109.

By arranging the molded resin 109 to expose the surfaces 134A while covering the other portions of the mounting terminals 134, the peripheries of the mounting terminals 134 may be supported by the molded resin 109 so that the positioning of the mounting terminals 134 with respect to the substrate 131 may be controlled. It is noted that solder balls or cylindrical/prismatic metal posts may be used as the mounting terminals 134. In a case where metal posts are used as the mounting terminals 134, metal posts made of copper may be connected to the connection pads 132 by solder, or the metal posts may be created by inducing precipitation growth of plating on the connection pads 132, for example. In a case where solder balls are used as the testing terminals 134, the diameter R7 of the testing terminals 134 may be 0.4 mm, for example, and in such a case, the diameter R8 of the flat surfaces 134A of the mounting terminals 134 may be 0.25 mm, for example.

The individual components 141 are electronic components that include electrodes 142. The electrodes 142 are electrically connected to the first connecting portions 136 by solder paste 143. In one embodiment, each of the individual components 141 may correspond to an elemental electric device such as a transistor, a diode, a resistor, or a capacitor, for example; that is, each of the components 141 may realize one of such functions (the components 141 are also referred to as ‘discrete components’).

The package 145 corresponding to another electronic component includes a package main body 146, a lead frame 147, and a semiconductor chip (not shown) that is accommodated within the package main body 146. The lead frame 147 is electrically connected to the semiconductor chip that is accommodated in the package main body 146. The lead frame 147 is electrically connected to the second connecting portions 137 by solder.

By arranging the mounting terminals 134 on the side of the substrate 131 on which the semiconductor chip 105 is mounted, plural electronic components (e.g., the individual components 141 and the package 145) may be arranged on the other side of the substrate 131, namely, on the opposite side with respect to the side on which the semiconductor chip 105 is mounted. In this way, the semiconductor device 130 may be mounted at high density. It is noted that the types of electronic components arranged on the substrate 131 are not limited to those of the illustrated example.

Although the present invention is shown and described with respect to certain preferred embodiments, it is obvious that equivalents and modifications will occur to others skilled in the art upon reading and understanding the specification. The present invention includes all such equivalents and modifications, and is limited only by the scope of the claims.

The present application is based on and claims the benefit of the earlier filing date of Japanese Patent Application No. 2004-358543 filed on Dec. 10, 2004, the entire contents of which are hereby incorporated by reference.

What is claimed is:

1. A semiconductor device comprising:
a semiconductor chip;
a substrate on which the semiconductor chip is mounted;
a mounting terminal that is arranged on a first side of the substrate; and
a testing terminal that is arranged on a second side of the substrate which second side is opposite the first side of the substrate.

2. The semiconductor device as claimed in claim 1, wherein
the semiconductor chip is mounted on the second side of the substrate; and
the testing terminal protrudes from the second side of the substrate further than the semiconductor chip.

3. The semiconductor device as claimed in claim 2, wherein
the semiconductor chip is connected to the substrate by a wire; and
the testing terminal protrudes from the second side of the substrate further than the wire.

4. The semiconductor device as claimed in claim 1, wherein
the semiconductor chip is covered by a resin, and a portion of the testing terminal is exposed through the resin.
